(19) United States
(12) Patent Application Publication
(10) Pub. No.: US 2025/0253185 A1
(43) Pub. Date: Aug. 7, 2025

(54) APPARATUS FOR PROCESSING SUBSTRATE

(71) Applicant: Samsung Electronics Co., Ltd., Suwon-si (KR)

(72) Inventors: Oh Chel KWON, Suwon-si (KR); Hyun-Chul KIM, Suwon-si (KR); Dae-Woong CHOI, Suwon-si (KR); Jin Hong PARK, Suwon-si (KR); Hyeong-Kwon JEONG, Suwon-si (KR)

(21) Appl. No.: 18/809,360

(22) Filed: Aug. 20, 2024

(30) Foreign Application Priority Data
Feb. 2, 2024 (KR) 10-2024-0016964
Apr. 1, 2024 (KR) 10-2024-0044173

(51) Int. Cl. H01L 21/687; H01L 21/67

(52) U.S. Cl. CPC H01L 21/68785; H01L 21/67034

(57) ABSTRACT

A substrate processing apparatus includes an upper vessel; a lower vessel including an accommodation space; a filler in the accommodation space and configured to support a substrate; and a pad below the filler to prevent the filler from changing position, in which the accommodation space includes a first groove having a first width, and a second groove having a second width smaller than the first width below the first groove, the filler includes a filler body that supports the substrate, and a plurality of legs on a lower surface of the filler body, the pad includes a plurality of fixing holes which are fixed to the second groove which fix the plurality of legs, and a first distance from the pad to a bottom surface of the first groove is greater than a second distance from the pad to a bottom surface of the second groove.

### CROSS-REFERENCE TO RELATED APPLICATION

This application claims priority from Korean Patent Application No. 10-2024-0016964 filed on Feb. 2, 2024 and No. 10-2024-0044173 filed on Apr. 1, 2024 in the Korean Intellectual Property Office and all the benefits accruing therefrom under 35 U.S.C. 119, the contents of which in their entireties are herein incorporated by reference.

### BACKGROUND

### 1. Field of the Inventive Concept

Aspects of the present inventive concept relate to a substrate processing apparatus, and more particularly, to a substrate processing apparatus using a supercritical fluid.

### 2. Description of the Related Art

As semiconductor elements become increasingly highly integrated, individual circuit patterns are further miniaturized to implement more semiconductor elements in the same area. Supercritical fluid is used in various processes (e.g., drying, vapor deposition) of the miniaturized semiconductor elements. This is because the supercritical fluid is a substance placed at a temperature and pressure above a critical point, and has the diffusivity of a gas and the solubility of a liquid. As an example of a drying process, the supercritical fluid readily penetrates a pattern on the substrate, and the supercritical fluid readily dissolves residual rinsing liquid (e.g., organic solvent). Accordingly, the rinsing liquid remaining between the patterns formed on the substrate is easily removed.

### SUMMARY

On the other hand, a filler that supports the substrate is disposed inside a vessel in which the supercritical process is performed. Since the supercritical fluid is supplied into the vessel at high pressure, the filler may swing. Furthermore, the swinging filler may scratch the inside of the vessel to generate metal particles, and a metal defect may occur on the substrate caused by the metal particles.

Aspects of the present inventive concept provide a substrate processing apparatus that may prevent filler from swinging to minimize metal defects.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

According to some example embodiments of inventive concepts, an apparatus for processing a substrate comprises an upper vessel; a lower vessel including an accommodation space; a filler in the accommodation space and configured to support a substrate; and a pad below the filler, the pad being configured to prevent the filler from changing position, wherein the accommodation space includes a first groove having a first width, and a second groove having a second width smaller than the first width below the first groove, wherein the filler includes a filler body configured to support the substrate, and a plurality of legs on a lower surface of the filler body, wherein the pad includes a plurality of fixing holes that fix the plurality of legs, and wherein a first distance from the pad to a bottom surface of the first groove is greater than a second distance from the pad to a bottom surface of the second groove.

According to some example embodiments of inventive concepts, an apparatus for processing a substrate comprises: a pad body including a first surface and a second surface; a first hole which penetrates the pad body; a second hole which is spaced apart from the first hole and penetrates the pad body; a plurality of fixing holes configured to penetrate the pad body and fix legs of a filler; a plurality of first bridge grooves which connect each of the plurality of fixing holes to the first hole; and a tunnel disposed along an edge of the first surface, the tunnel being connected to the plurality of fixing holes.

According to some example embodiments of inventive concepts, an apparatus for processing a substrate comprises: a vessel configured to process a substrate with a supercritical fluid, the vessel including an upper vessel and a lower vessel configured to be coupled in an openable and closable manner; a clamp configured to clamp the upper vessel and the lower vessel at a closed position of the vessel; a support on a lower surface of the upper vessel and configured to support the substrate at an opened position of the vessel; a filler positioned within the lower vessel and configured to support the lower surface of the substrate at the closed position of the vessel; and a pad below the filler, the pad being configured to prevent the filler from swinging, wherein the lower vessel includes an accommodation space for accommodating the filler, wherein the accommodation space includes a first groove having a first width and a second groove having a second width smaller than the first width below the first groove, wherein the filler includes a filler body that supports the substrate and a plurality of legs on a lower surface of the filler body, and wherein the pad includes: a pad body which includes a first surface and a second surface, the pad body being fixed into the second groove, a plurality of fixing holes which penetrate the pad body and are configured to fix the legs of the filler, a vent hole which penetrates the pad body and is aligned with a vent port of the lower vessel, a supply hole which penetrates the pad body and is aligned with a supply port of the lower vessel, a plurality of first bridge grooves which connect each of the plurality of fixing holes to the vent hole, and a tunnel disposed along an edge of the first surface of the pad body and connected to the plurality of fixing holes.

Specific details of other embodiments are included in the detailed description and drawings.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a conceptual diagram for explaining a substrate processing apparatus according to some embodiments of the present inventive concept;

FIG. 2 is a diagram for explaining a reactor shown in FIG. 1;

FIG. 3 is an enlarged view of a region A of FIG. 2;

FIG. 4 is a perspective view showing a first surface of a pad;

FIG. 5 is a plan view showing the first surface of the pad;

FIG. 6 is a perspective view taken along line B-B of FIG. 5;

FIG. 7 is a cross-sectional view taken along line C-C of FIG. 5;

FIG. 8 is a perspective view showing a second surface of the pad;

FIG. 9 is a plan view showing the second surface of the pad;

FIG. 10 is a side view for explaining a vent path in the substrate processing apparatus according to some embodiments of the present inventive concept;

FIG. 11 is a perspective view for explaining the vent path in the substrate processing apparatus according to some embodiments of the present inventive concept;

FIGS. 12 and 13 are diagrams for explaining the operation of the reactor;

FIG. 14 is a cross-sectional view for explaining a pad used in the substrate processing apparatus according to some embodiments of the present inventive concept;

FIG. 15 is a cross-sectional view for explaining the pad used in the substrate processing apparatus according to some embodiments of the present inventive concept;

FIG. 16 is a plan view for explaining the pad used in the substrate processing apparatus according to some embodiments of the present inventive concept;

FIG. 17 is a plan view for explaining the pad used in the substrate processing apparatus according to some embodiments of the present inventive concept; and

FIG. 18 is a diagram for explaining a system to which the substrate processing apparatus according to some embodiments of the present inventive concept is applied.

### DETAILED DESCRIPTION OF THE EMBODIMENTS

Embodiments of the present inventive concept will be described in detail below with reference to the accompanying drawings. The same reference numerals will be used for the same components in the drawings, and repeated description thereof will not be provided.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

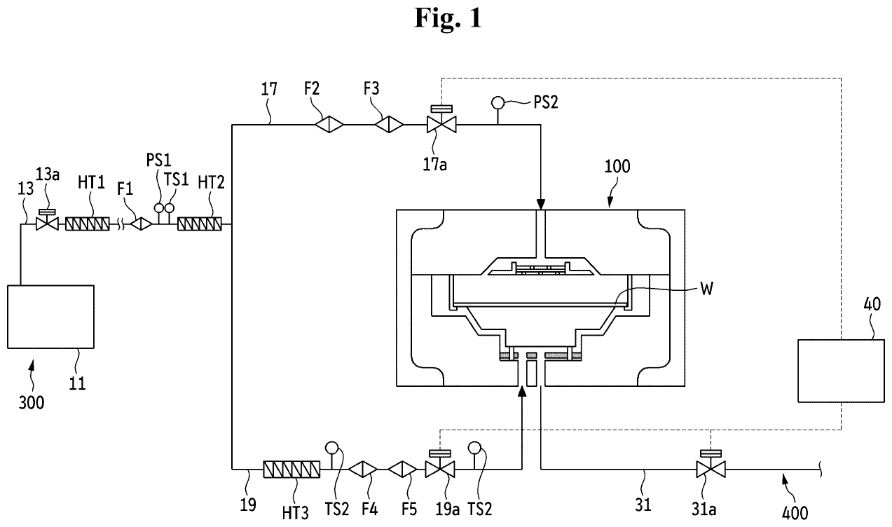

FIG. 1 is a conceptual diagram for explaining a substrate processing apparatus according to some embodiments of the present inventive concept.

Referring to FIG. 1, the substrate processing apparatus includes a reactor 100, a process fluid supply unit 300, a process fluid discharge unit 400, a controller 40, and the like. The controller 40 controls the operations of the reactor 100, the process fluid supply unit 300, the process fluid discharge unit 400, and the like.

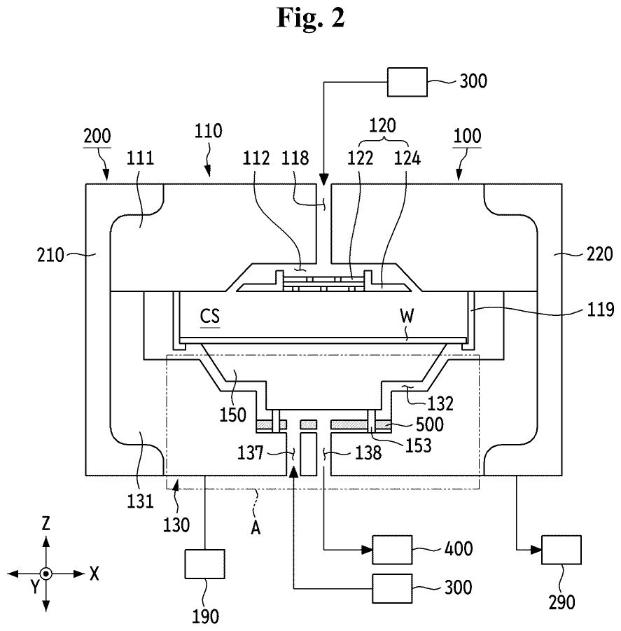

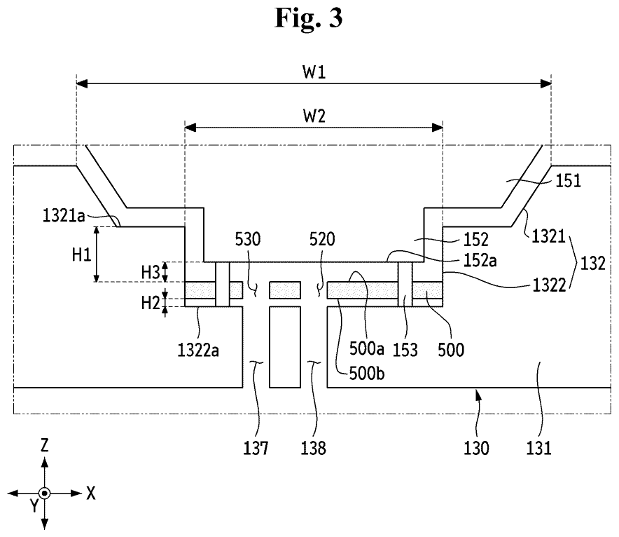

The reactor 100 provides a processing space in which the supercritical process proceeds. A specific structure of the reactor 100 will be specifically described below using FIGS. 2 and 3.

The process fluid supply unit 300 includes a fluid storage tank 11, an upstream supply line 13, a first supply line 17, a second supply line 19, and the like.

The fluid storage tank 11 may maintain the supercritical fluid in a supercritical state. The supercritical fluid may be, for example, carbon dioxide in a supercritical state. For example, the temperature of carbon dioxide in the supercritical state may be about 60° C., and the pressure of carbon dioxide in the supercritical state may be about 80 bar, but is not limited thereto.

The upstream supply line 13 is connected to the fluid storage tank 11, and may be branched into a first supply line 17 and a second supply line 19. The supercritical fluid may be supplied to the upper side of the reactor 100 along the first supply line 17, and the supercritical fluid may be supplied to the lower side of the reactor 100 along the second supply line 19.

At least one upstream supply valve 13a, at least one heater HT1 and HT2, and at least one filter F1 may be disposed on the upstream supply line 13. Furthermore, at least one pressure sensor PS1 and at least one temperature sensor TS1 may be disposed on the upstream supply line 13.

At least one supply valve 17a, at least one filter F2 and F3, at least one pressure sensor PS2, and the like may be disposed on the first supply line 17.

At least one supply valve 19a, at least one heater HT3, at least one filter F4 and F5, at least one temperature sensor TS2, and the like may be disposed on the second supply line 19.

Number and placement of valves 13a, 17a, and 19a, number and placement of filters F1, F2, F3, F4, and F5, number and placement of heaters HT1, HT2, and HT3, number and placement of pressure sensors PS1 and PS2, and number and placement of temperature sensors TS1 and TS2 may vary depending on the design.

The filters F1, F2, and F4 may be micro filters (MF), and the filters F3 and F5 may be ultra filter (UF), but the embodiments are not limited thereto. For example, all the filters F1, F2, F3, F4, and F5 may be filter of the same type or filters of different types from each other.

The process fluid discharge unit 400 may include a discharge line 31 connected to the reactor 100, and a discharge valve 31a installed in the discharge line 31. The process fluid discharge unit 400 discharges the atmosphere inside the reactor 100 (that is, the used process fluid, particles, etc.) to the outside.

The controller 40 may, for example, control the operation of at least one valve 17a, 19a, and 31a. The controller 40 may be configured to send and receive electrical signals to and from at least one valve 17a, 19a, and 31a, and may be configured to control the operation of at least one valve 17a, 19a, and 31a accordingly.

The controller 40 may be implemented as hardware, firmware, software, or any combination thereof. For example, the controller 40 may be a computing device such as a workstation computer, a desktop computer, a laptop computer, and a tablet computer. For example, the controller 40 may include a memory device such as a ROM (Read Only Memory) or a RAM (Random Access Memory), and a processor configured to execute predetermined computations and algorithms, for example, a micro processor, a CPU (Central Processing Unit), a GPU (Graphics Processing Unit), and the like. Additionally, the controller 40 may include a receiver and transmitter for receiving and transmitting electrical signals.

FIG. 2 is a diagram for explaining the reactor shown in FIG. 1. FIG. 3 is an enlarged view of a region A of FIG. 2.

First, referring to FIG. 2, a process (e.g., a drying process) using a supercritical fluid is performed in the reactor 100. The reactor 100 includes vessels 110 and 130, a baffle plate 120, a support 119, a filler 150, a clamper 200 (e.g., a clamp), a pad 500, and the like.

The vessels 110 and 130 provide a processing space CS for processing the substrate W. The vessels 110 and 130 include an upper vessel 110 and a lower vessel 130, and are coupled to be openable and closable. Specifically, a first drive unit 190 moves at least one of the upper vessel 110 and the lower vessel 130 to determine a relative position. The first drive unit 190 allows the upper vessel 110 and the lower vessel 130 to be switched between an opened position at which the processing space CS is opened and a closed position at which the processing space is sealed.

The upper vessel 110 includes a first body 111, a supply port 118, a first accommodation space 112, and the like.

The first body 111 serves as a body of the upper vessel 110, and has a supply port 118 and a first accommodation space 112 formed therein.

The supply port 118 may be installed to penetrate the first body 111. The supply port 118 is provided with a process fluid (i.e., supercritical fluid) from the process fluid supply unit 300 and delivers it to the first accommodation space 112.

The first accommodation space 112 may be formed on a lower surface (or bottom surface) of the first body 111. As shown, the first accommodation space 112 may have a shape that is recessed inward (e.g., upward) from the lower surface of the first body 111. A depth of the first accommodation space 112 may be, for example, 10 mm or more. As shown, a side surface of the first accommodation space 112 may have an inclined shape when viewed in cross-section. That is, the side surface and the upper surface of the first accommodation space 112 may form an angle greater than 90 degrees (e.g., 100 degrees to 160 degrees).

The baffle plate 120 is installed inside the first accommodation space 112. The baffle plate 120 diffuses the process fluid supplied by the supply port 118, and supplies it to the processing space CS.

Such a baffle plate 120 includes a base 124 and a perforated plate 122. The perforated plate 122 is fixed by the base 124, and may have a shape in which two or more layers are stacked, for example. A perforated position of the lower layer of the perforated plate 122 may be different from a perforated position of the upper layer of the perforated plate 122. That is, when viewed from the vertical direction, the perforated position of the lower layer of the perforated plate 122 are not aligned with the perforated position of the upper layer of the perforated plate 122. By not disposing the perforated positions in a line, the process fluid is sufficiently mixed and supplied to the substrate W through the first accommodation space 112 and the baffle plate 120.

The support 119 is installed on the lower surface of the upper vessel 110. When the vessels 110 and 130 are at the opened position (e.g., when the upper vessel 110 and the lower vessel 130 are in a spaced state), the support 119 is configured to support the substrate W.

The lower vessel 130 includes a second body 131, a supply port 137, a vent port 138, a second accommodation space 132, and the like.

The second body 131 serves as the body of the lower vessel 130, and has a supply port 137, a vent port 138, and a second accommodation space 132 formed therein.

The supply port 137 may be installed to penetrate the second body 131. The supply port 137 is provided with a process fluid (i.e., supercritical fluid) from the process fluid supply unit 300 and delivers it to the second accommodation space 132.

The vent port 138 may be installed to penetrate the second body 131. The vent port 138 exhausts the atmosphere (e.g., used process fluid, etc.) of the second accommodation space 132 and the processing space CS to the outside. An exhaust operation may be controlled by the operation of the process fluid discharge unit 400 connected to the vent port 138.

As shown, the second accommodation space 132 may have a shape that is recessed inward (e.g., downward) from the upper surface of the second body 131.

The filler 150 is installed in the lower vessel 130 to face the baffle plate 120, and specifically, the filler 150 is installed in the second accommodation space 132. When the vessels 110 and 130 are changed from the opened position to the closed position, the substrate W may be delivered from the support 119 to the filler 150 and supported by the filler 150, but the inventive concept is not limited thereto.

The clamper 200 clamps vessels 110 and 130 at the closed position. The clamper 200 may include, for example, two clamps 210 and 220, but is not limited thereto. The clamper 200 may include a first clamp 210 that clamps one side of the vessels 110 and 130 at the closed position (that is, one side on the basis of the first direction X as shown, e.g., in FIG. 2), and the second clamp 220 that clamps the other side of the vessels 110 and 130 at the closed position (that is, the other side on the basis of the first direction X).

The clamper 200 may be moved to a locked position and an unlocked position by the second drive unit 290. The locked position means a position of the clamper 200 that clamps the vessels 110 and 130, and the unlocked position means a position of the clamper 200 that does not clamp the vessels 110 and 130.

Further, an upper edge of the upper vessel 110 may have a curved shape, and a lower edge of the lower vessel 130 may have a curved shape. The inner surface of the first clamp 210 and the inner surface of the second clamp 220 may have complementary shapes to engage the curved shapes of the upper vessel 110 and the lower vessel 130.

Referring to FIG. 3, the second accommodation space 132 of the lower vessel 130 includes a first groove 1321 and a second groove 1322. The first groove 1321 has a first width W1, and the second groove 1322 has a second width W2 smaller than the first width W1 below the first groove 1321.

A filler (see 150 of FIG. 2) is disposed inside the second accommodation space 132, and configured to support the substrate W. The filler 150 includes filler bodies 151 and 152 that support the substrate W, and a plurality of legs 153 disposed on the lower surface of the filler bodies 151 and 152. The filler bodies 151 and 152 may include, for example, an upper filler body 151 disposed in the first groove 1321, and a lower filler body 152 disposed in the second groove 1322. A width of the upper filler body 151 may be greater than a width of the lower filler body 152, but the inventive concept is not limited thereto. The plurality of legs 153 may be provided in the second groove 1322 to be in contact with the bottom surface 1322a of the second groove 1322, but the present inventive concept is not limited thereto. The filler 150 may be a body that fills a portion of the second accommodation space 132 and that supports the wafer W when the wafer W is loaded in the reactor 100.

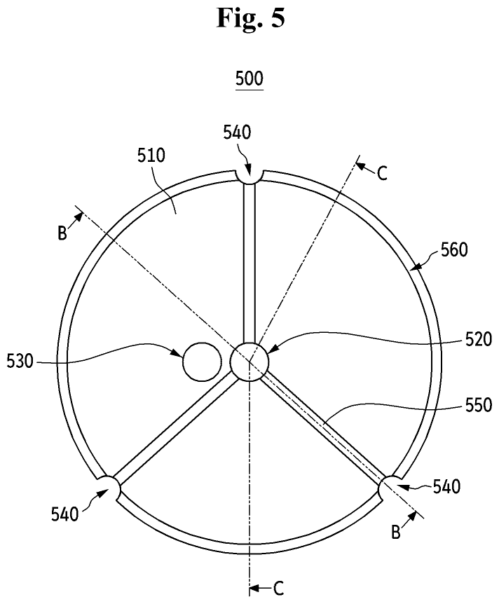

The pad 500 may be fixed inside the second groove 1322. Further, the pad 500 includes a plurality of fixators (see 540 of FIG. 5) to fix the plurality of legs 153. Since the side wall of the pad 500 comes into contact with the inner wall of the second groove 1322, the pad 500 may be fixed in position.

Furthermore, the pad 500 may be located at a lower portion (e.g., a downward direction based on the third direction Z) inside the second groove 1322.

Specifically, as shown in FIG. 3, a first distance H1 from the pad 500 (that is, the first surface 500a or upper surface of the pad 500) to the bottom surface 1321a of the first groove 1321 may be greater than a second distance H2 from the pad 500 (that is, the second surface 500b or lower surface of the pad 500) to the bottom surface 1322a of the second groove 1322.

Further, the second distance H2 from the pad 500 (i.e., the second surface 500b of the pad 500) to the bottom surface 1322a of the second groove 1322 may be smaller than a third distance H3 from the pad 500 (i.e., the first surface 500a of the pad 500) to the lower surface 152a of the filler bodies 151 and 152.

Due to the installation position of the pad 500, the space between the first surface 500a of the pad 500 and the lower surface 152a of the filler bodies 151 and 152 may be wider than a space between the second surface 500b of the pad 500 and the bottom surface 1322a of the second groove 1322.

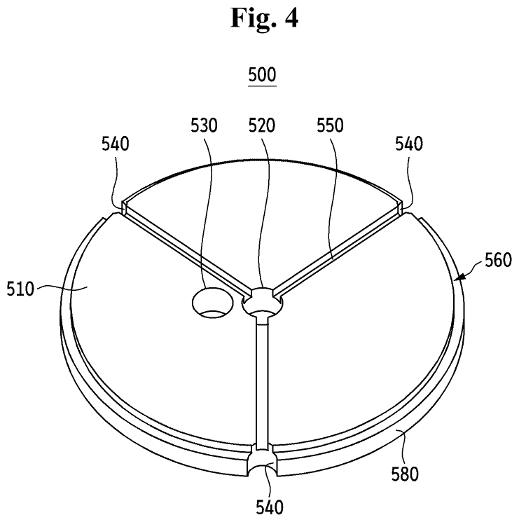

A specific structure of such a pad 500 will be specifically explained using FIGS. 4 to 9.

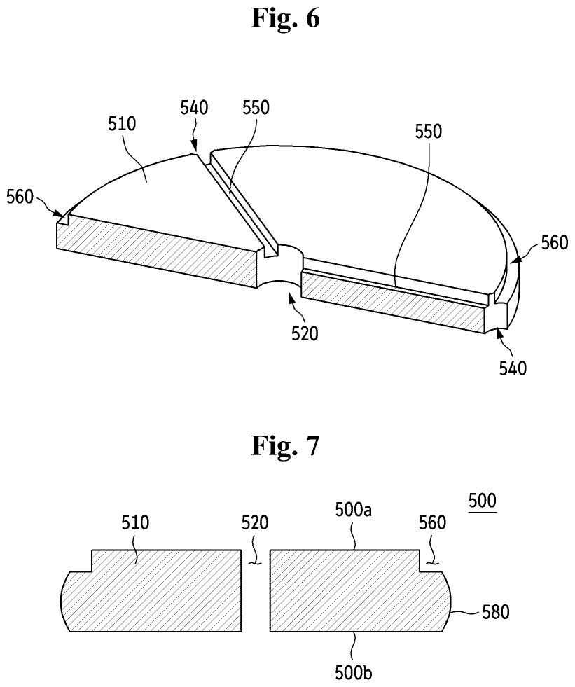

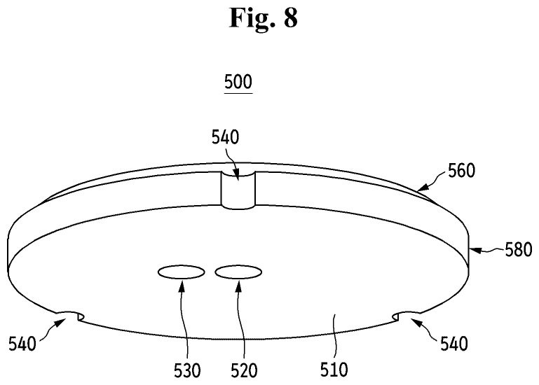

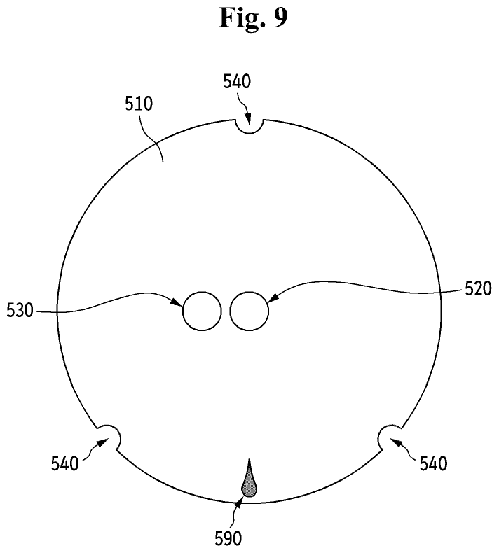

FIG. 4 is a perspective view showing the first surface 500a of the pad. FIG. 5 is a plan view showing the first surface of the pad. FIG. 6 is a perspective view taken along line B-B of FIG. 5. FIG. 7 is a cross-sectional view taken along line C-C of FIG. 5. FIG. 8 is a perspective view showing the second surface 500b of the pad. FIG. 9 is a plan view showing the second surface 500b of the pad.

Referring to FIGS. 4 to 9, the pad 500 includes a pad body 510, a first hole (or vent hole) 520, a second hole (or supply hole) 530, a plurality of fixators 540 (e.g., fixing holes), and the like.

The pad body 510 may have an approximately disc shape. The pad body 510 may include or be made of a material having wear resistance, chemical resistance, and heat resistance. For example, the pad body 510 may be PTFE (polytetrafluoroethylene), PFA (perfluoroalkoxy alkanes), PI (polyimide), PE (polyethylene), or PCTFE (polychlorotrifluoroethylene).

The first hole 520 is aligned with the vent port (138 of FIG. 3) of the lower vessel (130 of FIG. 3), and the second hole 530 may be aligned with the supply port (137 of FIG. 3) of the lower vessel 130.

The first hole 520 may be located at the center of the pad body 510, and the second hole 530 may be biased from the center of the pad body 510 toward the edge. For example, the second hole 530 may be positioned away from the center (or off-center) of the pad body 510.

The plurality of fixators 540 may correspond to the plurality of legs (153 of FIG. 3). The shape of the fixator 540 may correspond to the shape of the legs 153. For example, if leg 153 is a cylindrical post, the fixator 540 may be a semi-cylindrical hole (or semi-cylindrical groove) having an inner wall with which the outer wall of the cylindrical post may come into contact. For example, each fixator 540 may be an indentation in the edge of the pad body 510 that conforms to the shape of the leg 153 to which it corresponds.

When the filler 150 includes three legs 153 disposed at an interval of 120 degrees, pad 500 may also include three fixators 540 disposed at an interval of 120 degrees.

Because the legs 153 of the filler 150 are fixed in position by the fixator 540 of the pad 500, the filler 150 does not swing or change position, even when the process fluid is supplied at high pressure through the supply port 137 of the lower vessel 130. Furthermore, since the filler 150 does not swing, the legs 153 of the filler 150 do not scratch the bottom surface of the lower vessel 130 (i.e., the second groove (1322 of FIG. 3)). Therefore, particles that may occur due to scratching are no longer generated.

In addition, the pad 500 may further include a plurality of bridge grooves 550 that connect the first hole 520 to each of the plurality of fixators 540. The plurality of bridge grooves 550 may be formed in the first surface 500a of the pad body 510. The depth of the bridge groove 550 may be the same as or shallower than the depth of the fixator 540 to which it is connected.

Although each of the fixators 540 is shown as being connected to the first hole 520 by one bridge groove 550, the embodiment is not limited thereto. That is, each of the fixators 540 may be connected to the first hole 520 by two or more bridge grooves 550.

Further, the pad 500 may further include a tunnel 560 disposed along the edge of the first surface (500a of FIG. 3) of the pad body 510. The first surface 500a of the pad body 510 is a surface that faces the filler 150. The tunnel 560 is connected to at least one fixator 540. The depth of the tunnel 560 may be the same as or shallower than the depth of the fixator 540 to which it is connected. The depth of tunnel 560 may be realized in a variety of ways. For example, the tunnel 560 may be a notch extending around the edge of the first surface 500a of the pad body 510 in a circumferential direction. The notch may extend all the way around or part of the way around the circumference of the pad body 510. The notch may intersect each of the fixators 540.

In another embodiment, a tunnel may further be formed along the edge of the second surface (500b of FIG. 3) of the pad body 510.

As will be described below, various particles may pass through the tunnel 560 and the bridge groove 550 and be exhausted to the first hole (i.e., vent hole) 520. That is, the material remaining on or flowing into the outermost part of the pad 500 may pass through the tunnel 560 and the bridge groove 550, and may be exhausted to the first hole 520.

As shown in FIG. 7, a side surface 580 of the pad 500 may have an outwardly convex shape. By having such a configuration, the pad 500 may be smoothly fitted into the second groove (1322 of FIG. 3) and fixed to the second groove 1322.

As shown in FIG. 9, an alignment point 590 (e.g., an alignment mark) may be formed on the pad 500. A worker may install the pad 500 in place by the use of the alignment point 590.

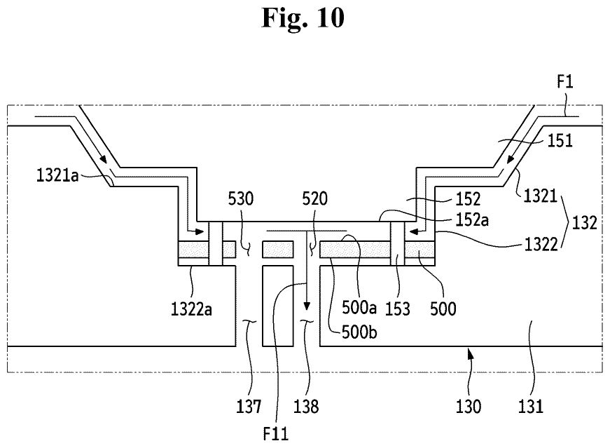

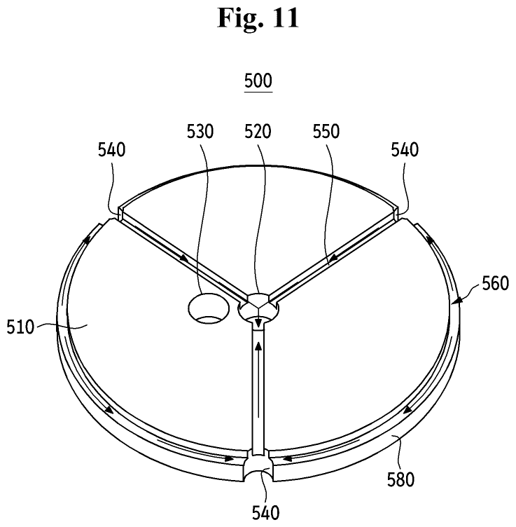

FIG. 10 is a side view for explaining a vent path in the substrate processing apparatus according to some embodiments of the present inventive concept. FIG. 11 is a perspective view for explaining the vent path in the substrate processing apparatus according to some embodiments of the present inventive concept.

Referring to FIG. 10, after a process (for example, a drying process) using a process fluid is performed in the reactor 100, a vent operation for removing the atmosphere (for example, the used process fluid, and various particles) in the process space CS is performed.

While the vent operation is being performed, the atmosphere inside the processing space CS moves between the upper filler body 151 and the first groove 1321, and between the lower filler body 152 and the second groove 1322 (see reference numeral F1). Then, the atmosphere passes through the first hole 520 of the pad 500 and the vent port 138, and is vented to an outside of the apparatus (see reference numeral F11).

While the vent operation is being performed, as shown in FIG. 11, the substance remaining on or flowing into the outermost part of the pad 500 moves along the tunnel 560 of the pad 500 and is delivered to the first hole 520 through the bridge groove 550. Further, the substance remaining in the fixator 540 may also be delivered to the first hole 520 through the bridge groove 550.

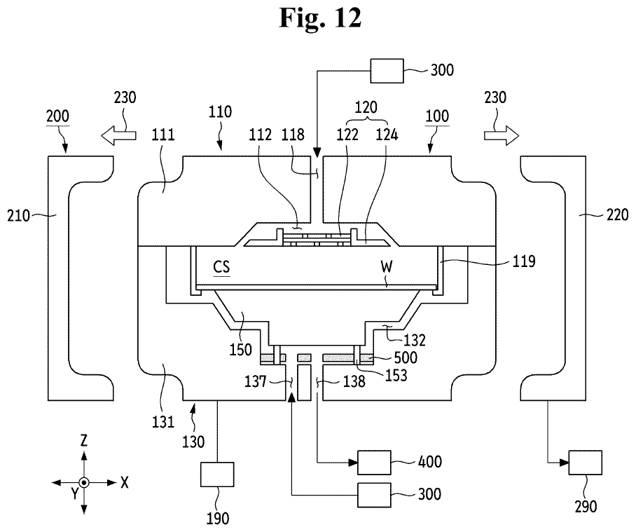

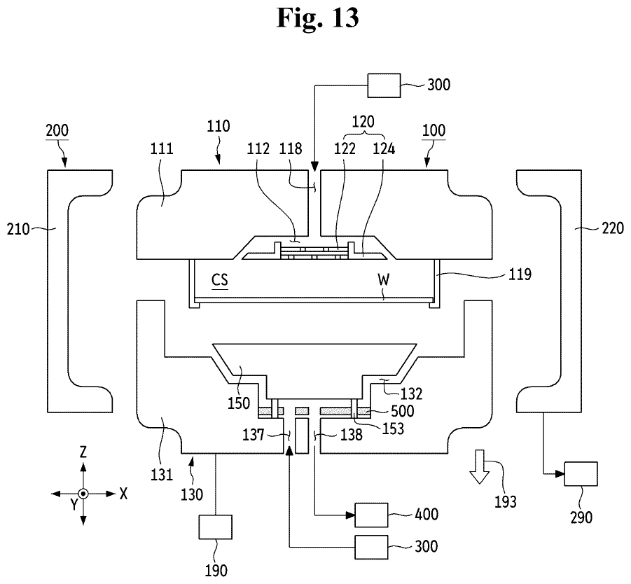

Next, the operation of the reactor will be explained using FIGS. 2, 12, and 13. FIGS. 12 and 13 are diagrams for explaining the operation of the reactor.

As shown in FIG. 2, the vessels 110 and 130 in which the supercritical process is performed are at the closed position, and the clamper 200 is at the locked position. That is, the upper vessel 110 and the lower vessel 130 come into contact with and engage with each other to seal the processing space CS, the first clamp 210 clamps the upper vessel 110 and the lower vessel 130 on one side, and the second clamp 220 clamps the upper vessel 110 and the lower vessel 130 on the other side.

In a state in which the substrate W is supported by the filler 150, the process fluid supply unit 300 supplies a process fluid (i.e., supercritical fluid) into the processing space CS. The processing liquid (e.g., rinsing liquid) remaining on the substrate W may be removed by the process fluid inside the processing space CS. Process fluids and/or particles inside the processing space CS are then vented outward from the vessels 110 and 130.

When the supercritical process is completed, as shown in FIG. 12, the clamper 200 moves from the locked position to the unlocked position by the second drive unit 290 (see reference numeral 230). That is, the first clamp 210 is spaced apart from one side of the vessels 110 and 130, and the second clamp 220 is spaced apart from the other side of the vessels 110 and 130.

As shown in FIG. 13, the vessels 110 and 130 move from the closed position to the opened position by the first drive unit 190 (see reference numeral 193). FIG. 13 exemplarily shows that the upper vessel 110 is fixed, the lower vessel 130 moves in the third direction Z. As the lower vessel 130 moves in the third direction Z, the processing space CS opens. As a result, a separated space (that is, an open space) between the upper vessel 110 and the lower vessel 130 is formed.

As the lower vessel 130 moves in the third direction Z, the substrate W moves from the filler 150 to the support 119. Thereafter, the substrate W is taken out of the vessels 110 and 130 by, for example, a transfer robot.

After that, a new substrate W is drawn into the vessels 110 and 130. As shown in FIG. 13, the vessels 110 and 130 are at the opened position, and the clamper 200 is also at the unlocked position. The transfer robot moves the substrate W to the support 119. Thereafter, the vessels 110 and 130 move from the opened position to the closed position. The clamper 200 moves from the unlocked position to the locked position. In the process in which the vessels 110 and 130 move to the closed position, the substrate W moves from the support 119 to the filler 150.

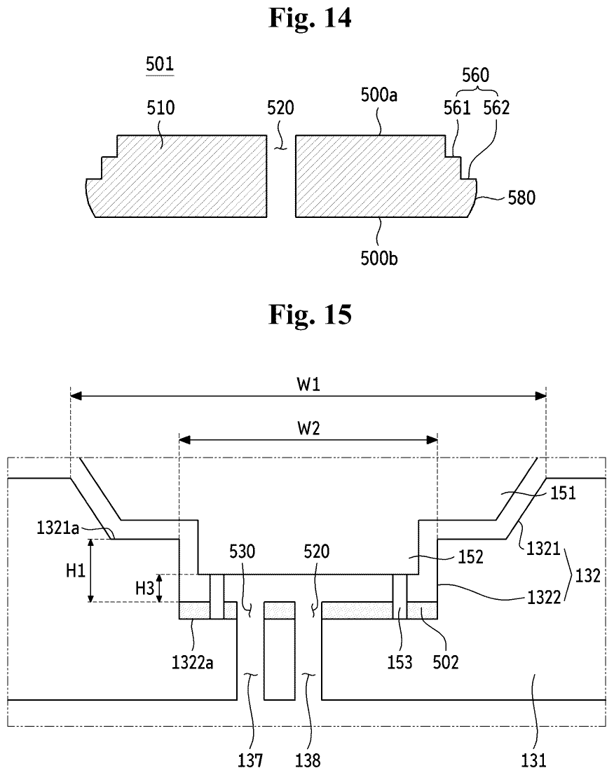

FIG. 14 is a cross-sectional view for explaining a pad used in the substrate processing apparatus according to some embodiments of the present inventive concept. For convenience of explanation, the explanation will focus on the points that are different from those explained using FIGS. 2 to 13.

Although the tunnel 560 of the pad 500 shown in FIG. 7 has a staircase shape of one floor or step, the tunnel 560 of the pad 501 shown in FIG. 14 may have a staircase shape of two floors or steps. The staircase shape of two floors may be a staircase shape that descends to the outermost edge of the pad 501. That is, the tunnel 560 includes a first step 561 connected to the first surface 500a, and a second step 562 connected to the first step 561. Unlike the shown example, the tunnel 560 may have a staircase shape of three or more floors or steps.

FIG. 15 is a cross-sectional view for explaining a pad used in the substrate processing apparatus according to some embodiments of the present inventive concept. For convenience of explanation, the explanation will focus on the points that are different from those explained using FIGS. 2 to 13.

The pad 500 shown in FIG. 3 is installed inside the second groove 1322 of the second accommodation space 132. The pad 500 may be disposed to be spaced apart from the bottom surface 1322a of the second groove 1322. A second distance H2 from the pad 500 to the bottom surface 1322a of the second groove 1322 is smaller than a first distance H1 from the pad 500 to the bottom surface 1321a of the first groove 1321, and a third distance H3 from the pad 500 to the lower surface 152a of the filler 150.

On the other hand, the pad 502 shown in FIG. 15 is disposed to be in contact with the bottom surface 1322a of the second groove 1322. In this way, since there is no space between the bottom surface 1322a of the second groove 1322 and the pad 502, it is possible to minimize occurrence of particles in the space between the bottom surface 1322a of the second groove 1322 and the pad 502.

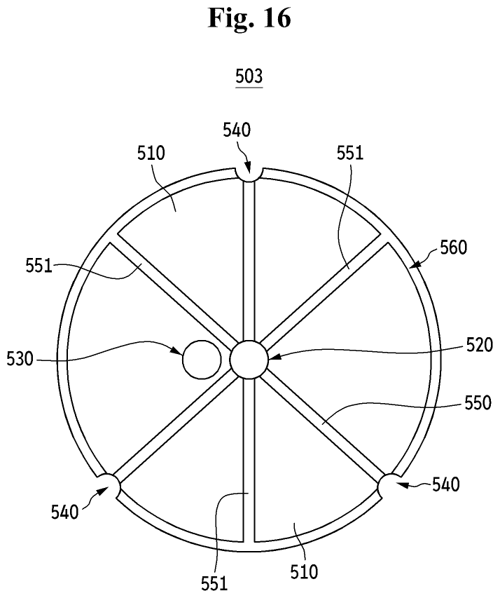

FIG. 16 is a cross-sectional view for explaining a pad used in the substrate processing apparatus according to some embodiments of the present inventive concept. For convenience of explanation, the explanation will focus on the points that are different from those explained using FIGS. 2 to 13.

The pad 503 shown in FIG. 16 further includes not only a plurality of bridge grooves 550 but also a plurality of bridge grooves 551. Each of the plurality of bridge grooves 551 connects the tunnel 560 to the first hole 520. A depth of the bridge groove 551 may be substantially the same as a depth of the bridge groove 550, but the inventive concept is not limited thereto. The depth of the bridge groove 551 may be substantially the same as the depth of the tunnel 560, but the inventive concept is not limited thereto.

By adding not only the bridge grooves 550 but also the bridge grooves 551, substances remaining on or flowing into the outermost part of the pad 500 may be exhausted to the first hole 520 through the bridge groove 551. That is, by adding the bridge grooves 551, exhaust performance may be improved.

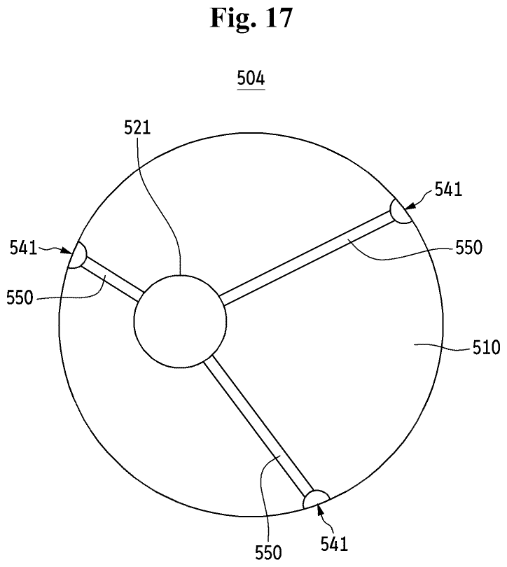

FIG. 17 is a cross-sectional view for explaining the pad used in the substrate processing apparatus according to some embodiments of the present inventive concept. For convenience of explanation, the explanation will focus on the points that are different from those explained using FIGS. 2 to 13.

The pad 500 shown in FIG. 5 includes a first hole 520 for ventilation and a second hole 530 for the process fluid supply. Furthermore, the fixator 540 has a shape of a hole passing through the pad body 510.

On the other hand, the pad 504 shown in FIG. 17 includes one hole 521 configured to perform both ventilation and process fluid supply. The hole 521 is installed to be biased toward the edge from the center of the pad body 510. For example, the hole 521 is positioned away from the center (or off-center) of the pad body 510. The hole 521 corresponds to the supply port (137 of FIG. 3) and the vent port (138 of FIG. 3).

Furthermore, the fixator 541 has a shape of a trench that does not penetrate the entire pad body 510. Therefore, the leg 153 fixed by the pad 504 does not come into contact with the bottom surface of the lower vessel 130, but comes into contact with the bottom surface of the trench. By doing so, particles that may be generated when the legs 153 of the filler 150 scratch the bottom surface of the lower vessel 130 are not generated.

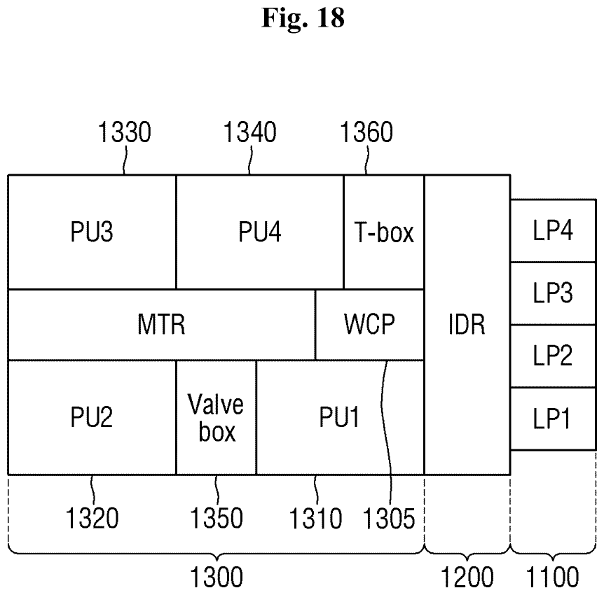

FIG. 18 is a diagram for explaining a system to which the substrate processing apparatus according to some embodiments of the present inventive concept is applied.

Referring to FIG. 18, the system includes a load port 1100, an index module 1200, and a process module 1300.

The load port 1100 includes a mounting table on which a container containing a plurality of substrates is disposed (see LP1 to LP4). The container may be, for example, but not limited to, a front opening unified pod (FOUP).

The index module (IDR) 1200 is disposed between the load port 1100 and the process module 1300. For example, the index module 1200 includes a rail installed within an indexing chamber, and an index robot that moves along the rail. The index robot includes an arm and a hand, and picks up the substrate located at the load port 1100 and transports it to the buffer chamber (WCP) 1305.

The process module 1300 includes a buffer chamber 1305, a transfer chamber MTR, a first process chamber (PU1) 1310, a second process chamber (PU2) 1320, a third process chamber (PU3) 1330, a fourth process chamber (PU4) 1340, a valve box 1350, an electronic box (T-box) 1360, and the like.

The buffer chamber 1305 temporarily stores the substrate delivered by the index robot of the index module 1200. Furthermore, the buffer chamber 1305 may temporarily store a substrate that has undergone predetermined processes in at least one of the process chambers 1310, 1320, 1330, and 1340.

A guide rail, and a transfer robot that moves along the guide rail are installed inside the transfer chamber MTR.

The first process chamber 1310, the valve box 1350, and the second process chamber 1320 may be sequentially disposed on one side of the transfer chamber MTR. Furthermore, the electronic box 1360, the fourth process chamber 1340, and the third process chamber 1330 may be sequentially disposed on the other side of the transfer chamber MTR. That is, the transfer chamber MTR is disposed to cross between the first process chamber 1310 and the fourth process chamber 1340, and between the second process chamber 1320 and the third process chamber 1330.

At least one of the first to fourth process chambers 1310 to 1340 may correspond to the reactor 100 of the substrate processing apparatus according to some embodiments of the present inventive concept. For example, a rinsing process may be performed in the first process chamber 1310, and a supercritical drying process for drying the rinsing liquid may be performed in the second process chamber 1320.

The valve box 1350 is a space in which pipes and valves for supplying a chemical liquid (e.g., at least one of a precursor, a reducing fluid, a developing fluid, a cleaning fluid, and a rinsing fluid) and/or a supercritical fluid (e.g., carbon dioxide) to at least one process chamber 1310, 1320, 1330, and 1340 are installed.

The electronic box 1360 may be a space in which a plurality of electrical devices are installed. For example, the electronic box 1360 may be installed with electrical equipment associated with a fourth process chamber 1340 disposed adjacent thereto, but the embodiment is not limited thereto.

Although the embodiments of the present inventive concept have been described above with reference to the accompanying drawings, the present inventive concept is not limited to the above embodiments, and may be fabricated in various different forms. Those skilled in the art will appreciate that the present inventive concept may be embodied in other specific forms without changing the technical spirit or essential features of the present inventive concept. Accordingly, the above-described embodiments should be understood in all respects as illustrative and not restrictive.

What is claimed is:

1. An apparatus for processing a substrate, the apparatus comprising:
an upper vessel;
a lower vessel including an accommodation space;
a filler in the accommodation space and configured to support a substrate; and
a pad below the filler, the pad being configured to prevent the filler from changing position,
wherein the accommodation space includes a first groove having a first width, and a second groove having a second width smaller than the first width below the first groove,
wherein the filler includes a filler body configured to support the substrate, and a plurality of legs on a lower surface of the filler body,
wherein the pad includes a plurality of fixing holes that fix the plurality of legs, and
wherein a first distance from the pad to a bottom surface of the first groove is greater than a second distance from the pad to a bottom surface of the second groove.

2. The apparatus for processing the substrate of claim 1,
wherein the second distance from the pad to the bottom surface of the second groove is smaller than a third distance from the pad to a lower surface of the filler body.

3. The apparatus for processing the substrate of claim 1,
wherein the pad includes:
a pad body,
a first hole which penetrates the pad body, and
a plurality of first bridge grooves, each first bridge groove of the plurality of bridge grooves connecting a respective fixing hole of the plurality of fixing holes to the first hole.

4. The apparatus for processing the substrate of claim 3, further comprising:
a second hole spaced apart from the first hole,
wherein the first hole is positioned to vent the atmosphere in the accommodation space, and
the second hole is configured to supply a process fluid into the accommodation space.

5. The apparatus for processing the substrate of claim 3,
wherein the pad body includes a first surface that faces the filler body, and a second surface that faces the bottom surface of the second groove, and
wherein the pad further includes a tunnel disposed along an edge of the first surface of the pad body, the tunnel being connected to the plurality of fixing holes.

6. The apparatus for processing the substrate of claim 5, further comprising:
at least one second bridge groove which connects the tunnel to the first hole.

7. The apparatus for processing the substrate of claim 5,
wherein the second surface of the pad body is in contact with the bottom surface of the second groove.

8. The apparatus for processing the substrate of claim 3,
wherein a center of the first hole is positioned away from a center of the pad body.

9. The apparatus for processing the substrate of claim 1,
wherein each of the plurality of fixing holes includes a hole which penetrates the entire thickness of the pad or a trench which does not penetrate the entire thickness of the pad.

10. The apparatus for processing the substrate of claim 1,
wherein a side surface of the pad has an outwardly convex shape.

11. The apparatus for processing the substrate of claim 1,
wherein the pad further includes an alignment mark.

12. The apparatus for processing the substrate of claim 1,
wherein the filler body includes a lower filler body in the second groove, and an upper filler body in the first groove,
wherein the upper filler body is connected to the lower filler body, and
wherein the upper filler body has a width wider than a width of the lower filler body.

13. The apparatus for processing the substrate of claim 1,
wherein the upper vessel includes a first supply port configured to supply a process fluid, and
wherein the lower vessel includes a second supply port configured to supply the process fluid and a vent port configured to exhaust used process fluid to an outside of the apparatus.

14. An apparatus for processing a substrate, the apparatus comprising:
a pad body including a first surface and a second surface;
a first hole which penetrates the pad body;
a second hole which is spaced apart from the first hole and penetrates the pad body;
a plurality of fixing holes configured to penetrate the pad body and fix legs of a filler;
a plurality of first bridge grooves which connect each of the plurality of fixing holes to the first hole; and
a tunnel disposed along an edge of the first surface, the tunnel being connected to the plurality of fixing holes.

15. The apparatus for processing the substrate of claim 14, further comprising:
at least one second bridge groove which connects the tunnel to the first hole.

16. The apparatus for processing the substrate of claim 14,
wherein a cross section of the tunnel has a staircase shape.

17. An apparatus for processing a substrate comprising:
a vessel configured to process a substrate with a supercritical fluid, the vessel including an upper vessel and a lower vessel configured to be coupled in an openable and closable manner;
a clamp configured to clamp the upper vessel and the lower vessel at a closed position of the vessel;
a support on a lower surface of the upper vessel and configured to support the substrate at an opened position of the vessel;
a filler positioned within the lower vessel and configured to support the lower surface of the substrate at the closed position of the vessel; and
a pad below the filler, the pad being configured to prevent the filler from swinging,
wherein the lower vessel includes an accommodation space for accommodating the filler,
wherein the accommodation space includes a first groove having a first width and a second groove having a second width smaller than the first width below the first groove,
wherein the filler includes a filler body that supports the substrate and a plurality of legs on a lower surface of the filler body, and
wherein the pad includes:
a pad body which includes a first surface and a second surface, the pad body being fixed into the second groove,
a plurality of fixing holes which penetrate the pad body and are configured to fix the legs of the filler,
a vent hole which penetrates the pad body and is aligned with a vent port of the lower vessel,
a supply hole which penetrates the pad body and is aligned with a supply port of the lower vessel,
a plurality of first bridge grooves which connect each of the plurality of fixing holes to the vent hole, and
a tunnel disposed along an edge of the first surface of the pad body and connected to the plurality of fixing holes.

18. The apparatus for processing the substrate of claim 17,
wherein a first distance from the pad to a bottom surface of the first groove is greater than a second distance from the pad to a bottom surface of the second groove, and
wherein the second distance from the pad to the bottom surface of the second groove is smaller than a third distance from the pad to a lower surface of the filler body.

19. The apparatus for processing the substrate of claim 17, further comprising:
at least one second bridge groove which connects the tunnel to the vent hole.

20. The apparatus for processing the substrate of claim 17,
wherein the second surface of the pad body is in contact with the bottom surface of the second groove.
